(19) United States
(12) Patent Application Publication
(10) Pub. No.: US 2023/0073590 A1
(43) Pub. Date: Mar. 9, 2023

(54) SEMICONDUCTOR STRUCTURE AND METHOD FOR MANUFACTURING SAME

(71) Applicant: CHANGXIN MEMORY TECHNOLOGIES, INC., Hefei City (CN)

(72) Inventor: Xiong LI, Hefei (CN)

(73) Assignee: CHANGXIN MEMORY TECHNOLOGIES, INC., Hefei City (CN)

(21) Appl. No.: 17/814,517

(22) Filed: Jul. 24, 2022

Related U.S. Application Data
(63) Continuation of application No. PCT/CN2021/131903, filed on Nov. 19, 2021.

(30) Foreign Application Priority Data
Sep. 6, 2021 (CN) 202111038401.2

(51) Int. Cl. H01L 27/108

(52) U.S. Cl. CPC H01L 27/10823; H01L 27/10876; H01L 27/10888

(57) ABSTRACT

A semiconductor structure includes: a semiconductor substrate, in which a trench is provided in the semiconductor substrate, and a gate is formed in the trench; and a doped layer, in which the doped layer is located in the semiconductor substrate on an outer side of the trench. In a direction perpendicular to the semiconductor substrate, the doped layer includes a transition layer and an ion implantation layer located on the transition layer. A doping concentration of the transition layer is less than a doping concentration of the ion implantation layer; and in the direction perpendicular to the semiconductor substrate, a top surface of the transition layer is not lower than a bottom surface of the gate.

### CROSS-REFERENCE TO RELATED APPLICATIONS

The present application is a continuation of International Application No. PCT/CN2021/131903, filed on Nov. 19, 2021, which claims priority to Chinese Patent Application No. 202111038401.2, filed on Sep. 6, 2021. The disclosures of these applications are hereby incorporated by reference in their entireties.

### BACKGROUND

With the rapid development of a very large scale integration circuit technology, a size of a semiconductor device is continuously reduced. Because the semiconductor device is sharply reduced, a thickness of a gate oxide layer of a transistor is reduced to be 2 nm or even smaller. When the size of the semiconductor device is proportionally reduced, a working voltage is not correspondingly reduced at an equal proportion, causing a very strong Gate-Induced-Drain-Leakage (GIDL) current effect of a short channel device, and thus affecting the reliability of the semiconductor device. Therefore, how to reduce the GIDL current effect of the semiconductor device is a problem to be urgently solved.

### SUMMARY

Embodiments of the disclosure relate to a semiconductor technology, and relate to, but are not limited to, a semiconductor structure and a method for manufacturing the same.

In a first aspect, the embodiments of the disclosure provide a semiconductor structure, including: a semiconductor substrate and a doped layer.

A trench is provided in the semiconductor substrate, and a gate is formed in the trench.

The doped layer is located in the semiconductor substrate on an outer side of the trench.

In a direction perpendicular to the substrate, the doped layer includes a transition layer and an ion implantation layer located on the transition layer; and in the direction perpendicular to the semiconductor substrate, a top surface of the transition layer is not lower than a bottom surface of the gate.

In a second aspect, the embodiments of the disclosure provide a method for manufacturing a semiconductor structure, including the following operations.

A doped layer is formed in a semiconductor substrate. The doped layer includes a transition layer and an ion implantation layer located on the transition layer, and a depth of the transition layer in the semiconductor substrate is greater than a depth of the ion implantation layer.

The semiconductor substrate formed with the doped layer is etched to form a trench in the semiconductor substrate. In a direction perpendicular to the substrate, a bottom surface of the trench is lower than a bottom surface of the transition layer.

A gate is formed in the trench. In the direction perpendicular to the substrate, a top surface of the gate is not lower than the bottom surface of the transition layer.

### BRIEF DESCRIPTION OF THE DRAWINGS

FIG. 1 is a schematic view I of a semiconductor structure provided by an embodiment of the disclosure.

FIG. 2 is a schematic view II of a semiconductor structure provided by an embodiment of the disclosure.

FIG. 3 is a schematic view III of a semiconductor structure provided by an embodiment of the disclosure.

FIG. 4 is a schematic view IV of a semiconductor structure provided by an embodiment of the disclosure.

FIG. 5 is a flowchart of a method for manufacturing a semiconductor structure provided by an embodiment of the disclosure.

FIG. 6 is a schematic view of forming a doped layer in a method for manufacturing a semiconductor structure provided by an embodiment of the disclosure.

FIG. 7 is a schematic view of forming a trench in a method for manufacturing a semiconductor structure provided by an embodiment of the disclosure.

FIG. 8 is a schematic view of a semiconductor structure.

FIG. 9 is a schematic view V of a semiconductor structure provided by an embodiment of the disclosure.

### DETAILED DESCRIPTION

In order to facilitate the understanding of the disclosure, the disclosure will be described more fully below with reference to related accompanying drawings. Preferred embodiments of the disclosure are shown in the accompanying drawings. However, the disclosure may be implemented in many different forms and is not limited to the embodiments described herein. Instead, these embodiments are provided for making the disclosure more thorough and complete.

Unless otherwise specified, all technical and scientific terms used herein have the same meanings as commonly understood by those skilled in the technical field to which the disclosure relates. The terms used in the specification of the disclosure are for the purpose of describing specific embodiments only, and are not intended to limit the disclosure. The term “and/or” used herein includes any and all combinations of one or more associated listed items.

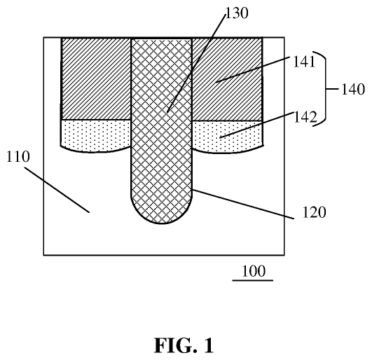

Embodiments of the disclosure provide a semiconductor structure. As shown in FIG. 1, the semiconductor structure 100 includes a semiconductor substrate 110 and a doped layer 140.

A trench 120 is provided in the semiconductor substrate 110. A gate 130 is formed in the trench 120.

The doped layer 140 is located in the semiconductor substrate 110 on an outer side of the trench 120.

In a direction perpendicular to the semiconductor substrate 110, the doped layer 140 includes a transition layer 142 and an ion implantation layer 141 located on the transition layer 142. A doping concentration of the transition layer 142 is less than a doping concentration of the ion implantation layer 141. In the direction perpendicular to the semiconductor substrate 110, a top surface of the transition layer 142 is not lower than a bottom surface of the gate 130.

The semiconductor substrate can include a P-type semiconductor material substrate (for example, a silicon (Si) substrate or a germanium (Ge) substrate, etc.), an N-type semiconductor substrate (for example, an Indium Phosphide (InP) substrate), and a composite semiconductor material substrate (for example, a Silicon Germanium (SiGe) substrate, etc.), a Silicon-on-Insulator (SOI) substrate, and a Germanium-on-Insulator (GeOI) substrate, etc. In one embodiment, the semiconductor substrate is a P-type semiconductor substrate. Specifically, N-type ions are first implanted in the substrate, a deep N-well is formed through high-temperature annealing, and then P-type ions are implanted above the deep N-well to form a P-well.

An array consisting of transistors can be formed on the semiconductor substrate and is used for implementing the storage and read-write of data, and other functions. The gates of the transistors are located in the trenches formed in the semiconductor substrate. In a transistor array, the gates in a same row can be communicated with each other and used for constituting a word line of an overall semiconductor device. In this way, the word line is buried in the semiconductor substrate, and therefore can be referred to as a Buried Word Line (BWL). The doped layers at the either side of the gate can respectively be a source and a drain. That is to say, discrete doped layers are respectively provided at either side of the trench.

The doped layers are formed by performing doping on the semiconductor substrate. Impurity types can be divided into N type and P type. The N type mainly includes phosphorus (P), arsenic (As), stibium (Sb), etc. The P type mainly includes boron (B) and indium (In), etc.

In the embodiments of the disclosure, the doped layer consists of a transition layer and an ion implantation layer. The transition layer is located below the ion implantation layer. During formation, the transition layer is first formed, and then the ion implantation layer is formed. The transition layer and the ion implantation layer may be the same in the material and the doped ions, and are different in that a concentration of the doped ions in the transition layer is less than a doping concentration of the ion implantation layer. That is to say, the ion implantation layer is a heavily doped area, and the transition layer is a lightly doped area. In this way, source and drain areas having graded junctions can be formed, reducing local electric fields between the source and drain areas and the gate, so that GIDL between the gate and the source and drain areas can be reduced.

In addition, in the embodiments of the disclosure, a top surface of the transition layer, i.e., an interface between the transition layer and the ion implantation layer, is not lower than a bottom surface of the gate. That is to say, an overlapping area of at least part of the gate and the doped layer is covered by the transition layer. Thus, the possibility of the occurrence of current leakage between the gate and the source and drain areas can be effectively reduced.

In some embodiments, in the direction perpendicular to the semiconductor substrate, the top surface of the transition layer is not lower than a top surface of the gate.

Herein, the top surface of the transition layer, i.e., the interface between the transition layer and the ion implantation layer, is parallel to the direction of the semiconductor substrate. The gate is buried in the semiconductor substrate, and the top surface of the gate is lower than the top surface of the transition layer Thus, the gate only overlaps with the transition layer, but does not overlap with the ion implantation layer.

Because the doping concentration of the transition layer is low, under the action of the electric field, current leakage is difficult to occur between the gate and the transition layer, either. Therefore, when the top surface of the transition layer is not lower than the top surface of the gate, GIDL between the gate and the source and drain areas can be effectively reduced.

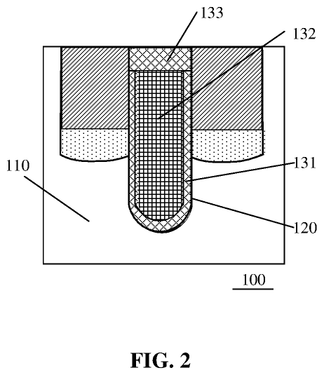

In some embodiments, as shown in FIG. 2, the gate 130 includes a gate oxide layer 131 and a gate conductive layer 132.

The gate oxide layer 131 covers an inner wall surface of the trench 120.

The gate conductive layer 132 is located in the trench 120 that is covered with the gate oxide layer 131.

The gate oxide layer is a thin film layer covering the inner wall surface of the trench. The material of the gate oxide layer may be silicon dioxide, etc.

The gate conductive layer is located in the trench that is covered with the gate oxide layer. The gate conductive layer may be formed from a metal material, for example, tungsten, nickel, or a tungsten nickel alloy, etc.

The gate oxide layer may be formed in a selective growth mode by using a growth process, for example, an In-Situ Steam Generation (ISSG) method. The ISSG is a thermal annealing deposition method, and relates to heating in a cavity and introducing oxygen atoms to be bound to silicon atoms in the semiconductor substrate to form a high-quality oxide thin film. The oxide thin film formed by using a deposition process, for example, a Chemical Vapor Deposition (CVD) method, can also be used as the gate oxide layer.

The gate conductive layer can be filled by using a deposition process. In some embodiments, the deposition process can include CVD, Physical Vapor Deposition (PVD), Plasma Enhanced CVD (PECVD), sputtering, Metal Organic Chemical Vapor Deposition (MOCVD), or Atomic Layer Deposition (ALD), etc.

In some embodiments, as shown in FIG. 2, in the trench 120 is further included an insulating layer 133.

The insulating layer 133 covers the gate 130.

The insulating layer covers the gate, so that the gate conductive layer is buried in the semiconductor substrate and the insulating layer. The material of the insulating layer may be an oxide material, or may also be silicon nitride, etc.

In some embodiments, the insulating layer can cover the gate conductive layer, and the gate oxide layer covers the inner wall of the whole trench. A method for forming the insulating layer can also be a growth process or a deposition process, etc.

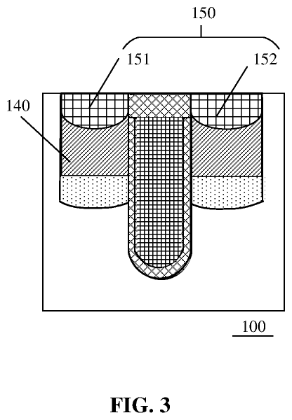

In some embodiments, as shown in FIG. 3, the semiconductor structure further includes a contact structure 150. The contact structure 150 is formed on the doped layer 140.

In the embodiments of the disclosure, the contact structure is formed on the ion implantation layer of the doped layer. The contact structure is made from a conductive material, for example, a semiconductor material or a metal material. In an embodiment, the material of the contact structure may be a polysilicon material. The contact structure is used for being in contact with a signal line, for example, a bit line, a ground line, etc., in the semiconductor device.

In some embodiments, as shown in FIG. 3, the contact structure 150 includes a bit line contact structure 151 and a storage node contact structure 152 that are discretely formed at either side of the trench. The bit line contact structure 151 and the storage node contact structure 152 are discretely formed in the ion implantation layer.

The bit line contact structure is used for being in contact with the bit line, i.e., the bit line is connected to the position of the bit line contact structure of each semiconductor structure, so that a bit line signal can be transmitted to a source in the semiconductor structure through the bit line contact structure.

The storage node contact structure is connected to a storage unit, for example a capacitor, etc. When the transistor of the semiconductor structure is in an on-state, a signal transmitted through the bit line contact structure can be transmitted to the storage node contact structure through a conductive channel that is formed in the semiconductor substrate under the action of the electric field, and then is transmitted to the storage unit, thereby achieving the storage of charges.

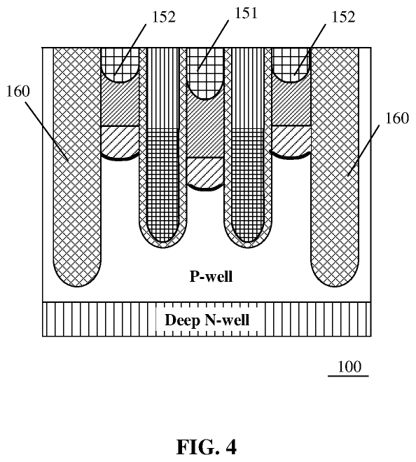

In some embodiments, as shown in FIG. 4, the semiconductor structure 100 further includes an isolation layer 160. The isolation layer 160 is located in the semiconductor substrate on an outer side of the doped layer 140. A depth of the isolation layer 160 is greater than or equal to a depth of the trench 120.

In one embodiment, the isolation layer is located on an outer side of the doped layer, so that the doped layers at different areas are electrically isolated from each other. A pair of transistors can be provided between every adjacent two isolation layers, and the pair of transistors can have a common source or a common drain.

The formation of the isolation layer can include: depositing a silicon nitride layer on the semiconductor substrate, and then patterning the silicon nitride layer to form a hard mask; then, etching the substrate to form a steep trench between adjacent transistor elements; and finally, filling an oxide in the trench to form the foregoing isolation layer. In the embodiments of the disclosure, the depth of the isolation layer is greater than or equal to the depth of the trench, so that the effect of electrical isolation is better.

In addition, in the embodiments of the disclosure, as shown in FIG. 4, the semiconductor substrate 110 can be composed of the deep N-well and the P-well located on the deep N-well, and then, the semiconductor structure is formed on the P-well.

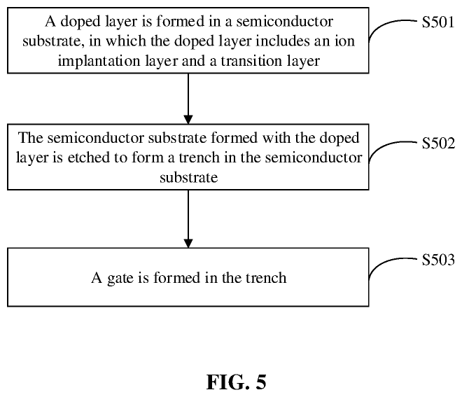

The embodiments of the disclosure further provide a method for manufacturing a semiconductor structure. As shown in FIG. 5, the method includes the following steps.

At S501, a doped layer is formed in a semiconductor substrate. The doped layer includes a transition layer and an ion implantation layer located on the transition layer, and a doping concentration of the transition layer is less than a doping concentration of the ion implantation layer.

At S502, the semiconductor substrate formed with the doped layer is etched, so as to form a trench in the semiconductor substrate. In a direction perpendicular to the substrate, a bottom surface of the trench is lower than a bottom surface of the transition layer.

At S503, a gate is formed in the trench. In the direction perpendicular to the substrate, a top surface of the gate is not lower than the bottom surface of the transition layer.

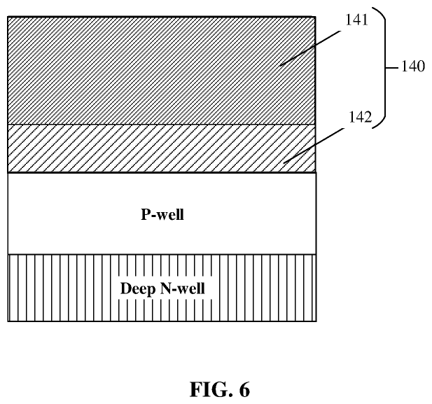

As shown in FIG. 6, in S501, the semiconductor substrate can be doped by performing ion implantation on the surface of the semiconductor substrate, so as to form the doped layer 140. The semiconductor substrate includes the surface and a back surface opposite to the surface. Herein, the surface of the semiconductor substrate refers to a surface distant from the deep N-well or a deep P-well. The surface of the semiconductor substrate and part of an area below the surface can be used for forming various elements. The process parameters of ion implantation include impurity types, implantation energy, and a doping dose. The impurity types can be divided into N type and P type. N-type impurities mainly include phosphorus, arsenic, stibium, and other elements, and P-type impurities mainly include boron, indium, and other elements. Exemplarily, in the embodiments of the disclosure, the selected implanted ions can be As+/P+. The implantation energy value of a first ion implantation can be 40 KeV.

In the embodiments of the disclosure, the doped layer 140 includes an ion implantation layer 141 and a transition layer 142. The doping concentration of the ion implantation layer is different from the doping concentration of the transition layer, and the depth of the transition layer is greater than the depth of the ion implantation layer. That is to say, at the bottom of the doped layer is the transition layer, and the ion implantation layer is located on the transition layer. The doping dose value of the first ion implantation can be 6×10¹² atoms/cm². When impurity atoms are implanted into the surface of the semiconductor substrate through an ion implanter, one ion implantation layer can be formed in the surface of the semiconductor substrate.

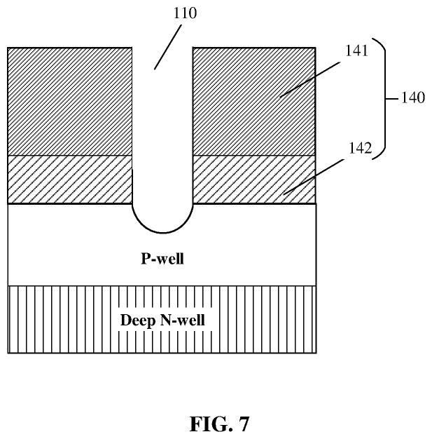

As shown in FIG. 7, in S502, the trench 120 can be formed in the semiconductor substrate by etching processing, including dry etching or wet drying, etc. At least part of the trench 120 is formed in the doped layer 140. In addition, part of the bottom of the trench 120 can also be extended into the semiconductor substrate 120 below the doped layer.

In some embodiments, the forming a doped layer in a semiconductor substrate includes the following operations.

A first ion implantation is performed on the semiconductor substrate to form the transition layer.

A second ion implantation is performed on part of the transition layer to form the ion implantation layer. The implantation energy of the first ion implantation is greater than the implantation energy of the second ion implantation, and an implantation dose of the first ion implantation is less than an implantation dose of the second ion implantation.

In the embodiments of the disclosure, the doped layer can be formed through two-step ion implantation. First, the transition layer is formed through the first ion implantation. The implantation energy of the first ion implantation is relatively large, and therefore, the first ion implantation can be performed to a deep position. However, the implantation dose of the first ion implantation is relatively small, so that a lightly doped transition layer can be obtained.

Then, the ion implantation layer is formed through the second ion implantation on the basis of the formed transition layer. Then, the implantation energy of the second ion implantation can be less than the implantation energy of the first ion implantation, so that the ion implantation layer is formed at a position with a smaller depth relative to the transition layer. In addition, the implantation dose of the second ion implantation is greater than the implantation dose of the first ion implantation, and therefore, a heavily doped ion implantation layer can be formed.

In some embodiments, the etching the semiconductor substrate formed with the doped layer to form a trench in the semiconductor substrate includes the following operations.

At least part of a surface of the doped layer is covered with a mask layer.

In a surface area that is not covered with the mask layer, the doped layer and at least part of the semiconductor substrate are etched to form the trench.

In some embodiments, the method further includes the following operation.

The mask layer on the surface of the doped layer is removed after the trench is formed.

A lithography technology can be used in the process of forming the trench, including: first forming a mask layer on the surface of the ion implantation layer, and then continuing to form a photoresist layer on the mask layer. A patterned mask and the photoresist layer are used to perform alignment exposure, and then a non-polymerized photoresist layer is removed. In this case, an opening is formed in the photoresist layer, and the mask layer can be downwardly etched through the opening. In this case, at least part of the surface of the ion implantation layer is covered with the mask layer. The ion implantation layer below the mask layer is then downwardly etched, so that after etching is completed, the trench is formed. Multiple trenches can be synchronously formed in the semiconductor substrate with the method, and are used for an array consisting of multiple semiconductor structures, thereby facilitating forming the semiconductor device that consists of a semiconductor array.

After the trench is formed, the processes such as the filling of each layer in the trench can be further completed, and then the mask layer on the surface of the semiconductor substrate is removed.

In some embodiments, the gate includes a gate oxide layer and a gate conductive layer. The forming a gate of a transistor in the trench includes the following operations.

The gate oxide layer is formed on an inner wall of the trench.

The gate conductive layer is formed in the trench with the inner wall covered with the gate oxide layer.

The gate oxide layer can be formed by using a growth process. The oxygen atoms are introduced to be bound to the silicon atoms in the semiconductor substrate to form a high-quality oxide thin film. A deposition process can also be used to deposit an oxide thin film to serve as the gate oxide layer.

The gate conductive layer can be filled by using a deposition process. A metal material is deposited in the trench and constitutes, together with the gate oxide layer, a buried gate. In an embodiment, the trench can pass through multiple transistors, and the deposited gate conductive layer can be connected to form a metal line to serve as a word line, i.e., a buried word line, of these transistors.

In some embodiments, the method further includes the following operations.

The gate conductive layer is etched back. A top surface of the etched gate conductive layer is not lower than the bottom surface of the transition layer.

An insulating material is filled in the trench to form an insulating layer. The insulating layer covers the gate.

In an embodiment, the back etching can be only performed on the gate conductive layer in the trench, so that the thickness of the gate conductive layer is reduced. After back etching, the surface of the gate conductive layer is lower than the surface of the substrate, so that the trench is formed on the surface of the gate conductive layer.

Next, the insulating material can be filled in the trench, and a surface of the insulating material is flush with the surface of the substrate, so as to form the insulating layer. The filling mode includes a deposition process (for example, CVD or plasma enhanced atomic layer deposition). The insulating material may be a nitride layer, an oxide layer, or a stacked film consisting of the nitride layer and the oxide layer. Exemplarily, in the embodiments of the disclosure, silicon nitride can be selected as the insulating material. The insulating layer is used for insulating the gate from the source/the drain, and burying the gate in the substrate.

In some embodiments, the method further includes the following operation.

A contact structure is formed on the surface of the ion implantation layer. The contact structure includes a bit line contact structure and a storage node contact structure. The bit line contact structure and the storage node contact structure are discretely formed at either side of the trench.

In some embodiments, the method further includes the following operation.

A contact structure is formed on the surface of the ion implantation layer. The contact structure includes a bit line contact structure and a storage node contact structure. The bit line contact structure and the storage node contact structure are discretely formed at either side of the trench.

In the embodiments of the disclosure, discrete ion implantation layers are etched back when the contact structure is formed. The etching mode includes, but is not limited to, dry etching and wet etching. After etching is completed, a first recessed area and a second recessed area are formed on the ion implantation layer. A conductive material, for example, a conductive metal nitride or polysilicon, etc., is deposited in the first recessed area and the second recessed area to form the bit line contact structure and the storage node contact structure.

In another embodiment, a conductive material layer can be directly deposited on the surface of the ion implantation layer to form the bit line contact structure and the storage node contact structure.

In some embodiments, the method further includes the following operation.

An isolation layer is formed. The isolation layer is located in the semiconductor substrate on an outer side of the doped layer; and a depth of the isolation layer is not less than a depth of the trench.

In an embodiment, multiple isolation layers can also be formed in the semiconductor substrate. The isolation layer is located on an outer side of the ion implantation layer and the transition layer, and used for isolating the semiconductor device. The formation process of the isolation layer can include: depositing a silicon nitride layer on the semiconductor substrate, and then patterning the silicon nitride layer to form a hard mask; then, etching the substrate to form a trench between adjacent elements; and finally, filling an insulating medium in the trench to form an element isolation layer.

In the embodiments of the disclosure, a pair of transistors can be provided between two isolation layers, and the pair of transistors can have a common source or a common drain. The pair of transistors are electrically isolated from another pair of transistors through the isolation layer. Moreover, the depth of the isolation layer is greater than or equal to the depth of the trench, so that the effect of electrical isolation is better.

Embodiments of the disclosure provide the following instance.

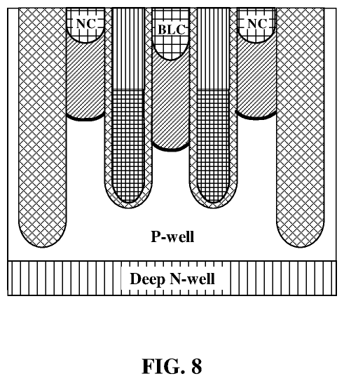

A traditional semiconductor device structure is as shown in FIG. 8. An S/D is formed in the ion implantation areas below the NCs and the BLC by using a one-step ion implantation mode. A doping concentration of the overlapping areas of NC ends and the BWL is too large, rendering the local electric field excessively high, so that the GIDL is increased, and thus a data storage time (VRT) is reduced.

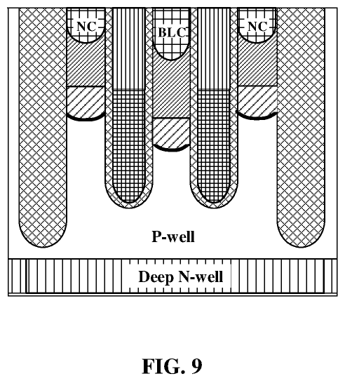

The embodiments of the disclosure provide a semiconductor device structure. As shown in FIG. 9, by using a two-step ion implantation mode, that is, the first ion implantation is performed at high energy and low dose, for example, As+/P+ ion implantation of 40 KeV and 6×10¹² atoms/cm², and the second ion implantation is performed at low energy and high dose, for example, As+/P+ ion implantation of 20 KeV and 4×10¹³ atoms/cm², an overlapping width of a heavily doped area and the gate is reduced. Light doping is performed on the overlapping area to form the graded junction, reducing the local electric field, thereby reducing the GIDL, and finally improving the problem that the data storage time of the semiconductor device is reduced.

The embodiments of the disclosure further provide a method for manufacturing the foregoing semiconductor device, including the following operations.

At step 1, ion implantation are performed twice on the semiconductor substrate to respectively form a lightly doped transition layer and a heavily doped ion implantation layer, and on this basis, an etching is performed to form trenches.

A first trench and a second trench having different depths can be synchronously or sequentially formed. Herein, the first trench is used for forming the gate, and the second trench is used for forming the isolation layer. Therefore, a depth of the second trench can be greater than a depth of the first trench.

At step 2, the gate is formed in the first trench, where the gate includes the gate oxide layer, the gate conductive layer, and the insulating layer. The gate conductive layer can extend along the first trench and passes through the multiple transistors to form the buried word line.

At step 3, the contact structure is formed in the surface of the ion implantation layer. The contact structure includes the bit line contact structure and the storage node contact structure.

It can be understood that compared with the solutions for forming a semiconductor structure in the related art, the embodiments of the disclosure at least have the following advantages.

1. The mode of forming the S/D of the semiconductor device is changed into the two-step ion implantation mode from the one-step ion implantation mode. The graded junction is formed in the overlapping area of the S/D and the BWL through the first ion implantation at high energy and low dose and the second ion implantation at low energy and high dose.

2. For a depth of the high energy and low dose, an interface of W/SiN (tungsten/silicon nitride) is used as a target depth, so that the overlapping width of the heavily doped area and the BWL is reduced, reducing the local electric field, thereby reducing the GIDL.

3. The design objectives of different semiconductor devices can be satisfied by reasonably adjusting the combination of the implantation energy and dose of the first ion implantation and the second ion implantation.

4. The semiconductor structure is suitable for an advanced DRAM product, and can improve the problem that the data storage time of a DRAM product is reduced.

It should be understood that “one embodiment” or “an embodiment” mentioned in the whole description means that particular features, structures, or characteristics related to the embodiments are included in at least one embodiment of the disclosure. Therefore, “in one embodiment” or “in an embodiment” appearing in the whole description does not necessarily refer to a same embodiment. In addition, these particular features, structures, or characteristics may be combined in one or more embodiments in any appropriate manner. It should be understood that sequence numbers of the foregoing processes do not mean execution sequences in various embodiments of the disclosure, and the execution sequences of the processes should be determined based on functions and internal logic thereof, and should not construct any limitation on the implementation processes of the embodiments of the disclosure. The foregoing sequence numbers of the embodiments of the disclosure are only for description, but do not represent superiority-inferiority of the embodiments.

It should be noted that in the disclosure, the terms “include”, “comprise” or any other variants thereof are intended to cover non-exclusive inclusion, so that a process, method, article or device that includes a series of elements includes not only those elements, but also other elements that are not explicitly listed or elements inherent to the process, method, article, or device. If no more limitations is made, an element defined by a phrase “including one . . . ” does not exclude that there are other identical elements in the process, method, article, or device including the elements.

The above are only implementations of the disclosure. However, the scope of protection of the disclosure is not limited thereto. Within the technical scope disclosed by the disclosure, any variation or substitution that can be easily conceived of by those skilled in the art shall all fall within the scope of protection of the disclosure. Therefore, the scope of protection of the disclosure shall be subject to the scope of protection of the claims.

In the embodiments of the disclosure, the gate is formed in the trench, the doped layer is provided on an outer side of the trench, and the doped layer includes the transition layer having a relatively low doping concentration and the ion implantation layer having a relatively high doping concentration. In this way, compared with a mode that the ion implantation layer is only included, and the ion implantation layer and the gate have a large overlapping area, a local electric field is reduced by using the transition layer in an overlapping area of the doped layer and the gate in the embodiments of the disclosure, thereby improving the GIDL problem.

What is claimed is:

1. A semiconductor structure, comprising:
a semiconductor substrate, wherein a trench is provided in the semiconductor substrate, and a gate is formed in the trench; and
a doped layer, wherein the doped layer is located in the semiconductor substrate on an outer side of the trench;
wherein in a direction perpendicular to the semiconductor substrate, the doped layer comprises a transition layer and an ion implantation layer located on the transition layer;
wherein a doping concentration of the transition layer is less than a doping concentration of the ion implantation layer; and in the direction perpendicular to the semiconductor substrate, a top surface of the transition layer is not lower than a bottom surface of the gate.

2. The semiconductor structure of claim 1, wherein in the direction perpendicular to the semiconductor substrate, the top surface of the transition layer is not lower than a top surface of the gate.

3. The semiconductor structure of claim 1, wherein the gate comprises a gate oxide layer and a gate conductive layer;
wherein the gate oxide layer covers an inner wall surface of the trench; and
the gate conductive layer is located in the trench that is covered with the gate oxide layer.

4. The semiconductor structure of claim 2, wherein an insulating layer is further comprised in the trench;
wherein the insulating layer covers the gate.

5. The semiconductor structure of claim 1, further comprising a contact structure formed on the doped layer.

6. The semiconductor structure of claim 5, wherein the contact structure comprises a bit line contact structure and a storage node contact structure that are discretely formed at either side of the trench, wherein the bit line contact structure and the storage node contact structure are discretely formed in the ion implantation layer.

7. The semiconductor structure of claim 6, wherein the semiconductor structure further comprises an isolation layer; wherein the isolation layer is located in the semiconductor substrate on an outer side of the doped layer; and a depth of the isolation layer is greater than or equal to a depth of the trench.

8. A method for manufacturing a semiconductor structure, comprising:
forming a doped layer in a semiconductor substrate, wherein the doped layer comprises a transition layer and an ion implantation layer located on the transition layer, wherein a doping concentration of the transition layer is less than a doping concentration of the ion implantation layer;
etching the semiconductor substrate formed with the doped layer to form a trench in the semiconductor substrate, wherein in a direction perpendicular to the substrate, a bottom surface of the trench is lower than a bottom surface of the transition layer; and
forming a gate in the trench, wherein in the direction perpendicular to the substrate, a top surface of the gate is not lower than the bottom surface of the transition layer.

9. The method of claim 8, wherein the forming the doped layer in the semiconductor substrate comprises:
performing a first ion implantation on the semiconductor substrate to form the transition layer; and
performing a second ion implantation on part of the transition layer to form the ion implantation layer, wherein an implantation energy of the first ion implantation is greater than an implantation energy of the second ion implantation, and an implantation dose of the first ion implantation is less than an implantation dose of the second ion implantation.

10. The method of claim 8, wherein the etching the semiconductor substrate formed with the doped layer to form the trench in the semiconductor substrate comprises:
covering at least partial area of a surface of the doped layer with a mask layer; and
in an area that is not covered with the mask layer, etching the doped layer and at least part of the semiconductor substrate to form the trench.

11. The method of claim 10, further comprising:
after forming the trench, removing the mask layer on the surface of the doped layer.

12. The method of claim 8, wherein the gate comprises a gate oxide layer and a gate conductive layer; and the forming the gate of a transistor in the trench comprises:
forming the gate oxide layer on an inner wall of the trench; and
forming the gate conductive layer in the trench with the inner wall covered with the gate oxide layer.

13. The method of claim 12, further comprising:
etching back the gate conductive layer, wherein a top surface of the gate conductive layer etched is not lower than the bottom surface of the transition layer; and
filling an insulating material in the trench to form an insulating layer, wherein the insulating layer covers the gate.

14. The method of claim 8, further comprising:
forming a contact structure on a surface of the ion implantation layer, wherein the contact structure comprises a bit line contact structure and a storage node contact structure, wherein the bit line contact structure and the storage node contact structure are discretely formed at either side of the trench.

15. The method of claim 8, further comprising:
forming an isolation layer, wherein the isolation layer is located in the semiconductor substrate on an outer side of the doped layer; and a depth of the isolation layer is not less than a depth of the trench.
